(19) United States
(12) Patent Application Publication
(10) Pub. No.: US 2026/0277272 A1
(43) Pub. Date: Sep. 17, 2026

(54) DISPLAY DEVICE AND ELECTRONIC DEVICE INCLUDING THE SAME

(71) Applicant: Samsung Display Co., Ltd., Yongin-Si (KR)

(72) Inventors: DASOM GU, Yongin-si (KR); JI-HOON KIM, Yongin-si (KR); SUNGGUK AN, Yongin-si (KR); CHUL HO JEONG, Yongin-si (KR); KYUNGMIN CHOI, Yongin-si (KR)

(21) Appl. No.: 19/567,828

(22) Filed: Mar. 16, 2026

(30) Foreign Application Priority Data
Mar. 17, 2025 (KR) 10-2025-0033877

(51) Int. Cl. G06F 1/16

(52) U.S. Cl. CPC G06F 1/1656; G06F 1/1641; G06F 1/1643

(57) ABSTRACT

An electronic device includes a display module, a support plate, and a protection member. The display module includes a display panel. The display panel has a first non-foldable area, a foldable area, and a second non-foldable area defined therein. The foldable area is disposed between the first non-foldable area and the second non-foldable area. The support plate is disposed below the display panel. In the support plate, a plurality of opening parts overlapping with the foldable area is defined. The protection member overlaps with at least one of the plurality of opening parts in a planar view. In the protection member, an instantaneous rate of change of a second shear thickening corresponding to a second shear thickening rate may be greater than an instantaneous rate of change of a first shear thickening corresponding to a first shear rate. The second shear thickening rate is greater than the first shear thickening rate.

### CROSS-REFERENCE TO RELATED APPLICATIONS

This application claims priority to and benefits of Korean Patent Application No. 10-2025-0033877 under 35 U.S.C § 119, filed on Mar. 17, 2025, in the Korean Intellectual Property Office, the contents of which are incorporated herein in its entirety by reference.

### BACKGROUND

### 1. Technical Field

The present disclosure relates to a display device configured to prevent sagging of a lattice and protect a display panel. Particularly, the present disclosure relates to a display device having a protection member mounted therein, the protection member having shear thickening characteristics above and below a lattice, and an electronic device including the display device.

### 2. Description of the Related Art

A flexible display device may have a display panel repeatedly bent, folded or rolled. In order for the above, a supporting plate having a lattice shape is provided below the display panel. An impurity or dust may penetrate into the lattice of the supporting plate. Conventionally, a thin film composed of a thermoplastic polyurethane (TPU) material was disposed below the lattice to prevent penetration of an impurity to the display panel. However, because the thin film composed of a TPU material had weak impact absorption capability, the thin film was unable to protect the display panel.

In addition, thin glass is used above the display panel to improve flexibility of a flexible display device. In case that the glass becomes a thin film, flexibility of a flexible display device may be improved, but strength becomes weaker, and durability also becomes degraded.

Therefore, a technique is required to prevent penetration of an impurity into a lattice of a flexible display device and improve impact resistance.

### SUMMARY

An object of the present disclosure is to provide a display device configured to prevent sagging of lattice inside a plate and protect a display panel, and an electronic device including the same. Particularly, an object of the present disclosure is to provide a display device having a protection member mounted therein, the protection member including shear thickening material above and below a lattice, and an electronic device including the same.

A display device according to one embodiment of the present disclosure may include a display module, a support plate, and a protection member. The display module may include a display panel having a first non-foldable area, a foldable area, and a second non-foldable area therein. The foldable area can be disposed between the first non-foldable area and the second non-foldable area. The support plate may be disposed below the display panel and have a plurality of opening parts overlapping with the foldable area. The protection member may overlap with at least one of the plurality of opening parts and include a shear thickening material.

In one embodiment of the present disclosure, the protection member may include a first material and a second material. The first material may include at least one of polyethylene glycol and polypropylene glycol. The second material may include at least one of silicon dioxide, calcium carbide, polystyrene, and polymethylmethacrylate.

In one embodiment of the present disclosure, at least a portion of the protection member may be disposed below the support plate and overlap with at least one of the first non-foldable area and the second non-foldable area.

In one embodiment of the present disclosure, at least a portion of the protection member may be disposed in the plurality of opening parts.

In one embodiment of the present disclosure, at least a portion of the protection member may be disposed between the display panel and the support plate.

The display device according to one embodiment of the present disclosure may further include a first digitizer and a second digitizer. The first digitizer may be disposed below the support plate and overlap with the first non-foldable area. The second digitizer may be disposed below the support plate and overlap with the second non-foldable area. The second digitizer may be spaced apart from the first digitizer. At least a portion of the protection member may be disposed between the first digitizer and the second digitizer.

In one embodiment of the present disclosure, in the protection member, an instantaneous rate of change of a second shear thickening corresponding to a second shear thickening rate greater than the first shear thickening rate may be greater than an instantaneous rate of change of a first shear thickening corresponding to a first shear rate.

In one embodiment of the present disclosure, the protection member may have a modulus greater than or equal to 50 MPa and smaller than or equal to 150 MPa at a temperature greater than or equal to 19° C. and smaller than or equal to 21° C. The protection member may have a modulus greater than or equal to 400 MPa and smaller than or equal to 1 GPa at a temperature greater than −19° C. and smaller than or equal to −21° C.

In one embodiment of the present disclosure, a thickness of the protection member may be greater than or equal to 8/m and smaller than or equal to 4 mm

In one embodiment of the present disclosure, the protection member may further include at least one of a carbon nanotube and a nanotube.

In one embodiment of the present disclosure, the protection member may further include at least one among urethane, acryl, and a thermoplastic polyurethane.

The display device according to one embodiment of the present disclosure may further include a window disposed on the display module. The window may include an elastomer.

In one embodiment of the present disclosure, the window may have a modulus greater than or equal to 0.1 MPa and smaller than or equal to 0.9 GPa at a temperature greater than or equal to 19° C. and smaller than or equal to 21° C. The window may have a modulus greater than or equal to 0.1 MPa and smaller than or equal to 2 GPa at a temperature greater than or equal to −19° C. and smaller than or equal to −21° C.

In one embodiment of the present disclosure, a thickness of the window may be greater than or equal to 16 μm and smaller than or equal to 85/m.

An electronic device according to one embodiment of the present disclosure may include a display module, a support plate, and a protection member. The display module may include a display panel having a first non-foldable area, a foldable area, and a second non-foldable area defined therein. The foldable area may be disposed between the first non-foldable area and the second non-foldable area. The support plate may be disposed below the display panel. A plurality of opening parts overlapping with the foldable area in a planar view of the support plate may be defined. The protection member may overlap with at least one of the plurality of opening parts in a planar view. In the protection member, an instantaneous rate of change of a second shear thickening corresponding to a second shear thickening rate greater than the first shear thickening strain rate may be greater than an instantaneous rate of change of a first shear thickening corresponding to a first shear rate.

According to one embodiment of the present disclosure, the protection member may include a first material and a second material. The first material may include at least one of polyethylene glycol and polypropylene glycol. The second material may include at least one among silicon dioxide, calcium carbonate, polystyrene, and polymethylmethacrylate.

In one embodiment of the present disclosure, at least a portion of the protection member may be disposed below the support plate and overlap with at least one of the first non-foldable area and the second non-foldable area.

In one embodiment of the present disclosure, at least a portion of the protection member may be disposed in the plurality of opening parts.

In one embodiment of the present disclosure, at least a portion of the protection member may be disposed between the display panel and the support plate.

In one embodiment of the present disclosure, the protection member may have a modulus greater than or equal to 50 MPa and smaller than or equal to 150 MPa at a temperature greater than or equal to 19° C. and smaller than or equal to 21° C. The protection member may have a modulus greater than or equal to 400 MPa and smaller than or equal to 1 GPa at a temperature greater than or equal to −19° C. and smaller than or equal to −21° C.

The present disclosure may provide a display device including a display panel configured to prevent sagging lattice in a plate and an electronic device including the same. Particularly, a protection member including a shear thickening material above or below a lattice mounted therein and an electronic device including the same may be provided.

### BRIEF DESCRIPTION OF THE DRAWINGS

These and/or other features will become apparent and more readily appreciated from the following description of the embodiments, taken in conjunction with the accompanying drawings in which:

FIG. 1A is an illustration of unfolded electronic device according to one embodiment of the present disclosure;

FIG. 1B is an illustration of a folded electronic device according to one embodiment of the present disclosure;

FIG. 2 is an illustration of an exploded diagram of an electronic device according to one embodiment of the present disclosure;

FIG. 3 is an cross-section taken along the I-I′ line shown in FIG. 1A;

FIG. 4 is an illustration of a cross-section of a display panel according to one embodiment of the present disclosure;

FIG. 5 is an magnified view of the AA area shown in FIG. 3;

FIG. 6A and FIG. 6B are graphs illustrating a physical feature of a protection member according to one embodiment of the present disclosure;

FIG. 7A, 7B and FIG. 7C are illustrations of a manufacturing process of a protection member according to one embodiment of the present disclosure;

FIG. 8A, 8B, 8C, 8D and FIG. 8E each is an illustration of a magnified view of a cross-section of an electronic device according to different embodiments of the present disclosure;

FIG. 9 is an illustration of a block diagram of an electronic device according to one embodiment of the present disclosure; and

FIG. 10 are schematic diagrams of electronic devices according to various embodiments.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

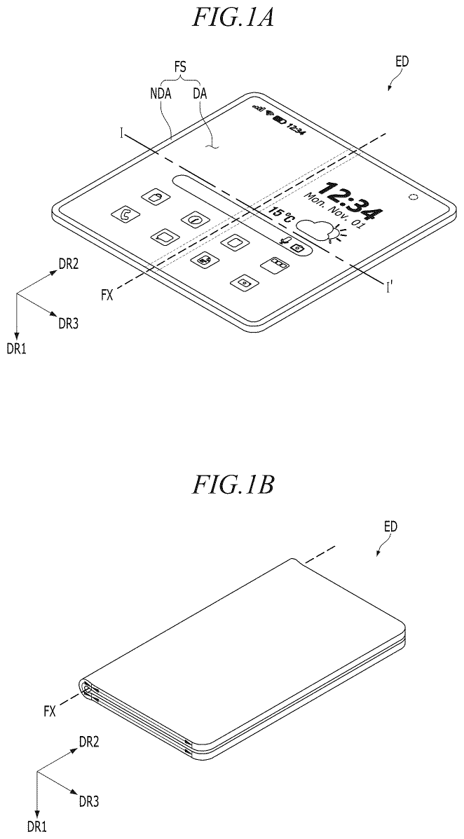

FIG. 1A is an illustration of unfolded electronic device ED according to one embodiment of the present disclosure. FIG. 1B is an illustration of a folded electronic device ED according to one embodiment of the present disclosure.

A first direction DR1 may be a thickness direction of the electronic device ED. A second direction DR2 may be a direction perpendicular to the first direction DR1. A third direction DR3 may be a direction perpendicular to the first direction DR1 and the second direction DR2.

Referring to FIG. 1A, the electronic device ED may be a device being activated by an electrical signal. For example, the electronic device ED may be configured to display an image through a display surface FS parallel to a second direction DR2 and a third direction DR3. The display surface FS of the electronic device ED may include a display area DA and a non-display area NDA. The non-display area NDA may surround the display area DA.

Referring to FIG. 1A and FIG. 1B, the electronic device ED may be folded with respect to a folding axis FX extended in a direction parallel to the second direction DR2.

As described herein, in-folding refers to a state when the electronic device ED is folded not to expose the display surface FS to an exterior and out-folding refers to a state when an electronic device ED is folded to expose the display surface FS to an exterior. In FIG. 1B, the electronic device ED is illustrated to be in-folded, but the present disclosure is not limited thereto. In one embodiment of the present disclosure, the electronic device ED may be in-folded or out-folded. In another embodiment of the present disclosure, the electronic device ED may be both in-folded and out-folded.

In FIG. 1A and FIG. 1B, a smartphone is illustrated as the electronic device ED. However, the electronic device ED of the present disclosure is not limited thereto. In one or more embodiments, the electronic device ED may include at least any one among large-sized flexible displays and medium-sized to small-sized flexible displays. For example, the large-sized flexible displays may include a television, a monitor, and a signboard. The medium-sized to small-sized flexible displays may include a tablet, a built-in display of a home appliance, a smart watch, and a smartphone.

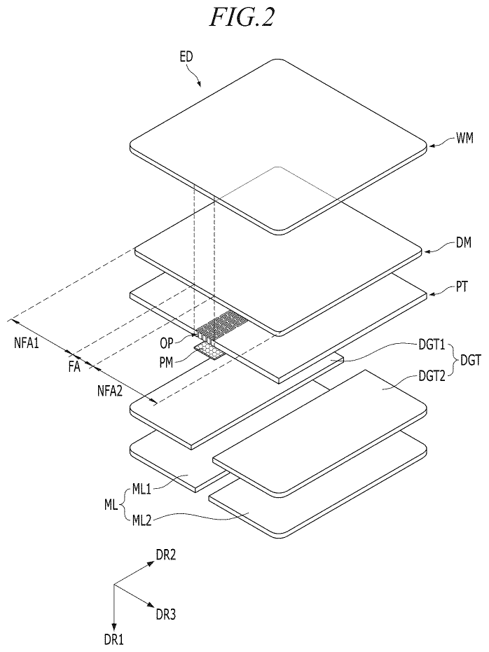

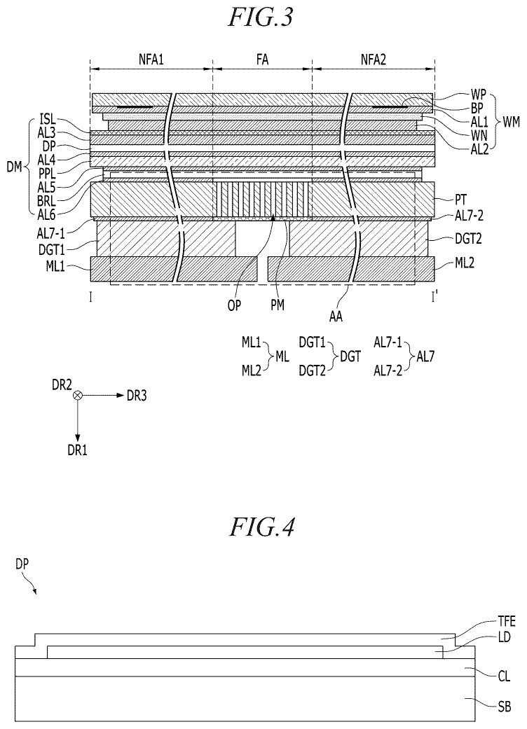

FIG. 2 is an exploded diagram of an electronic device ED according to one embodiment of the present disclosure. FIG. 3 is an illustration of a portion of a cross-section taken along the I-I′ line shown in FIG. 1A.

Referring to FIG. 2 and FIG. 3, the electronic device ED according to one embodiment of the present disclosure may include a window module WM, a display module DM, a support plate PT, a protection member PM, digitizers DGT1, DGT2, and metallic layers ML1, ML2.

The window module WM may be disposed above the display module DM and configured to define an exterior shape of an electronic device ED and protect the display module DM. The window module WM may include a material having flexibility. Therefore, when the electronic device ED is being folded with respect to the folding axis FX (see FIG. 1A), the window module WM may be folded together.

The window module WM may include a window protection layer WP, a bezel pattern BP, a first adhesive layer AL1, a window WN, and a second adhesive layer AL2.

The window protection layer WP may be disposed on the window WN to be configured to prevent deformation of the display module DM by protecting the window WN and the functional layers disposed below the window WN from a pressure applied from outside.

The window protection layer WP may include a flexible plastic material. The window protection layer WP may include at least any one of polyimide (PI) and Polyethylene terephthalate (PET).

A thickness of the window protection layer WP may be preferably greater than or equal to 50 μm. A modulus of the window protection layer WP at a room temperature (about greater than or equal to 19° C. and less than or equal to 21° C.) may be greater than or equal to about 3 GPA. A modulus of the window protection layer WP at a low temperature (about greater than or equal to −19° C. and less than or equal to −21° C.) may be greater than or equal to about 4 GPa. However, the present disclosure is not limited thereto, and a thickness and a modulus per temperature of the window protection layer WP may be limitlessly modified according to different embodiments.

A bezel pattern BP may be disposed in the non-display area NDA shown in FIG. 1A. The bezel pattern BP may be disposed on one side of the window WN or one side of the window protection layer WP. FIG. 3 exemplarily illustrates a bezel pattern BP disposed below the window protection layer WP. However, the present disclosure is not limited to what is illustrated in the figure, and the bezel pattern BP may be disposed above the window protection layer WP. The bezel pattern BP may be formed through a coating process as a colorized light-blocking film.

A first adhesive layer AL1 may be disposed between the window protection layer WP and the window WN to attach the window protection layer WP and the window WN to each other. The first adhesive layer AL1 may include Pressure Sensitive Adhesive (PSA), Optically Clear Adhesive (OCA), or Optical Clear Resin (OCR). Adhesive layers AL2 through AL7 described hereinafter may also include a same adhesive agent as in the first adhesive layer AL1.

The window WN may include a transparent material. Accordingly, light emitted from the display module DM may transmit through the window WN. For example, the window WN may include at least any one of a glass substrate and a synthetic resin film. The synthetic resin film may include at least any one of polyimide (PI) and polyethylene terephthalate (PET). In addition, the window WN may include an elastomer.

In one embodiment of the present disclosure, a thickness of the window WN may be greater than or equal to 15/m and smaller than or equal to 100 μm. Preferably, the thickness of the window WN may be greater than or equal to 16 μm and smaller than or equal to 85/m. If the thickness of the window WN is smaller than 16 μm, elements disposed below the window WN may not be effectively protected. If the thickness of the window WN is greater than 85/m, foldability or bendability of the electronic device ED may be degraded due to the thick thickness of the window WN.

In addition, a modulus of the window WN at a room temperature (about greater than or equal to 19° C. and less than or equal to 21° C.) may be about greater than or equal to 0.6 GPa and smaller than or equal to 0.9 GPa. In addition, a modulus of the window WN at a low temperature (about greater than or equal to −19° C. and smaller than or equal to −21° C.) may be about greater than or equal to 1 GPa and smaller than or equal to 2 GPa. However, a thickness and a modulus per temperature of the window WN are not limited thereto.

In one embodiment of the present disclosure, in the window WN, the plurality of synthetic resin films may be attached by an adhesive agent. In another embodiment of the present disclosure, in the window WN, the glass substrate and at least one or more synthetic resin film may be attached by an adhesive agent.

The second adhesive layer AL2 may be interposed between the window WN and the display module DM to attach the window WN and the display module DM to each other.

In one embodiment of the present disclosure, the window module WM may not be provided.

The display module DM may include an impact absorption layer ISL, a third adhesive layer AL3, a display panel DP, a fourth adhesive layer AL4, a panel protection layer PPL, a fifth adhesive layer AL5, a barrier layer BRL, and a sixth adhesive layer AL6.

The impact absorption layer ISL may be disposed above the display panel DP. The impact absorption layer ISL may be configured to absorb an impact delivered from an upper portion of the display panel DP to protect the display panel DP. The impact absorption layer ISL may include a flexible plastic material. For example, the impact absorption layer ISL may include a synthetic resin film. The synthetic resin film may include at least any one of polyimide (PI), polycarbonate, polyamide, triacetylcellulose, and polyethylene terephthalate (PET).

The third adhesive layer AL3 may be interposed between the impact absorption layer ISL and the display panel DP to attach the impact absorption layer ISL and the display panel DP to each other.

The display panel DP may be configured to emit light. In the display panel DP, a first non-foldable area NFA1, a foldable area FA, and second non-foldable area NFA2 may be defined. The foldable area FA may overlap with the folding axis FX shown in FIG. 1A and FIG. 1B. The foldable area FA of the display panel DP may include a flexible material. Accordingly, in case that the electronic device ED is folded around the folding axis FX, the foldable area FA may be also bent. The foldable area FA may be interposed between the first non-foldable area NFA1 and the second non-foldable area NFA2.

The display panel DP may include a plurality of pixels, and the plurality of pixels may each include a light-emitting diode and a pixel circuit configured to control a current value flowing through the light-emitting diode. For example, the display panel DP may be any one of an organic light-emitting diode display panel, a quantum dot light-emitting display panel, a micro-LED display panel, a liquid crystal display panel, an electrophoretic display panel, and an electrowetting display panel. A light-emission layer of the organic light-emitting display panel may include an organic light-emitting material. An inorganic light-emitting display panel may include a quantum dot light-emitting display panel and a micro light-emitting display panel, both of which include an inorganic material as a light-emission layer.

The fourth adhesive layer AL4 may be interposed between the display panel DP and the panel protection layer PPL to attach the display panel DP and the panel protection layer PPL to each other.

The panel protection layer PPL may be disposed below the display panel DP. The panel protection layer PPL may be configured to absorb an impact delivered from a lower portion of the display panel DP to protect the display panel DP. The panel protection layer PPL may include a flexible plastic material. For example, the panel protection layer PPL may include polyethylene terephthalate (PET).

The fifth adhesive layer AL5 may be interposed between the panel protection layer PPL and the barrier layer BRL to attach the panel protection layer PPL and the barrier layer BRL to each other.

The barrier layer BRL may be disposed below the panel protection layer PPL. The barrier layer BRL may be configured to prevent deformation of the display panel DP due to pressure. For example, the barrier layer BRL may include at least any one of polyimide (PI) and polyethylene terephthalate (PET).

The sixth adhesive layer AL6 may be interposed between the barrier layer BRL and the support plate PT to attach the barrier layer BRL and the support plate PT to each other.

In one embodiment of the present disclosure, at least any one of the impact absorption layer ISL, the third adhesive layer AL3, the fourth adhesive layer AL4, the panel protection layer PPL, the fifth adhesive layer AL5, the barrier layer BRL, and the sixth adhesive layer AL6 may not be provided.

The support plate PT may be disposed below the display panel DP to support the display panel DP. The support plate PT may be interposed between the display panel DP and the protection member PM.

The support plate PT may include an insulating material or a non-metallic material. For example, the support plate PT may include carbon fiber reinforced plastic (CFRP) or glass fiber reinforced plastic (GFRP).

The support plate PT may have a plurality of opening parts OP defined therein. The plurality of opening parts OP may be arranged to have a lattice shape in a plan view. The plurality of opening parts OP may improve flexibility of the foldable area FA. In addition, the plurality of opening parts OP may be disposed in the foldable area FA in the first direction DR1.

The protection member PM may be disposed below the support plate PT. The protection member PM may be configured to prevent introduction of an impurity to the display module DM through the plurality of opening parts OP.

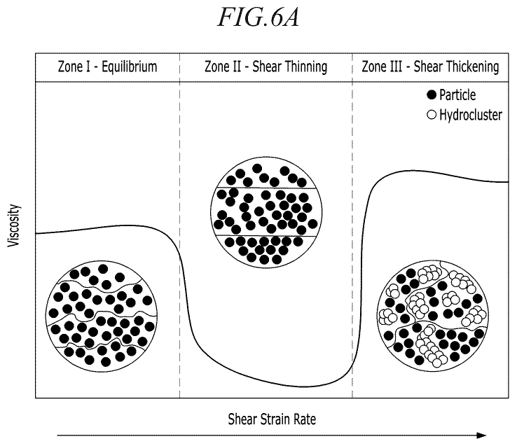

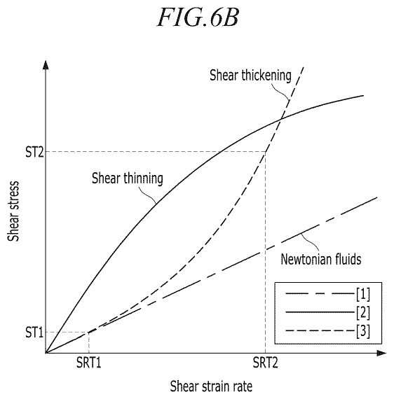

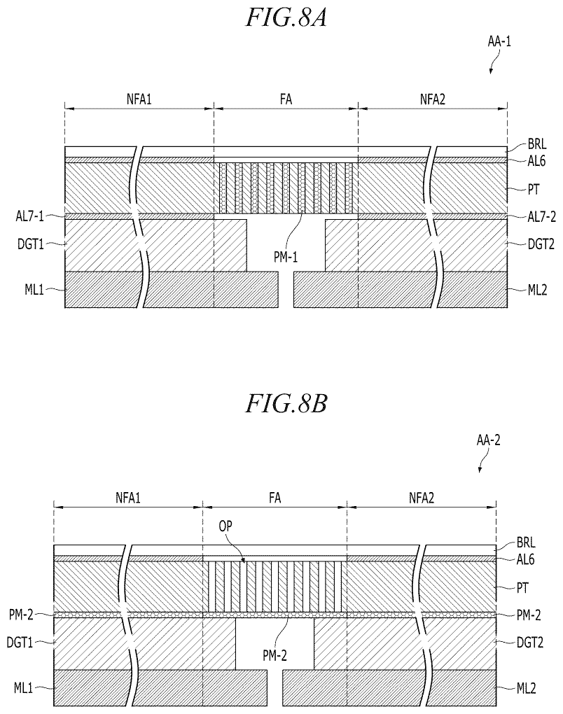

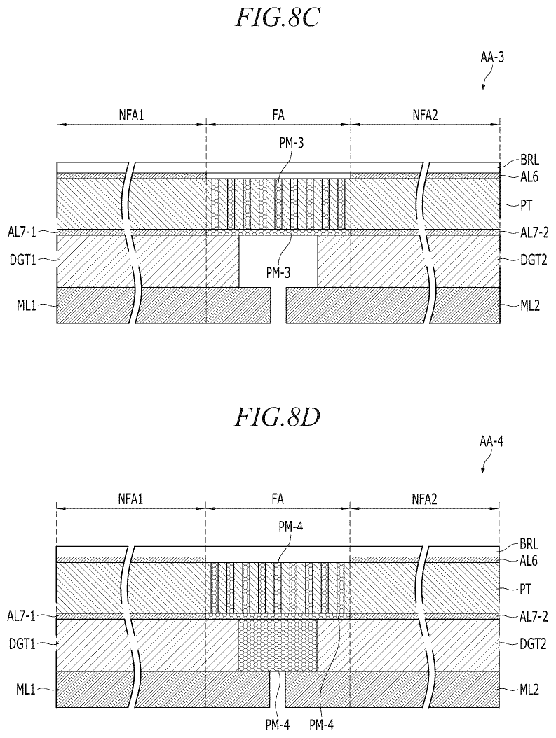

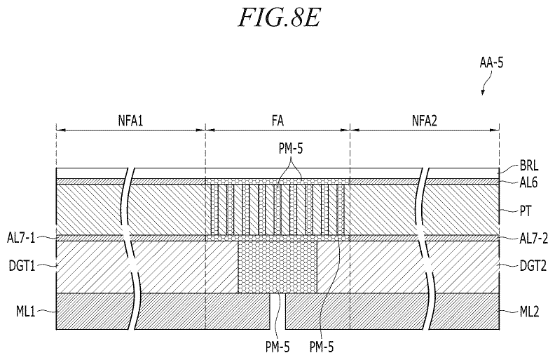

Hereinafter, detailed descriptions about a material and a feature of the protection member PM will be described in the descriptions about FIG. 5 through FIG. 6B. In addition, detailed descriptions about a position of the protection member PM will be described in the descriptions about FIG. 8A through FIG. 8E.

An electronic device ED according to one embodiment of the present disclosure may include a seventh adhesive layer AL7-1, AL7-2.

A first portion AL7-1 of the seventh adhesive layer AL7 may be interposed between the support plate PT and the first digitizer DGT1 to attach the support plate PT and the first digitizer DGT1 to each other. A second portion AL7-2 of the seventh adhesive layer AL7 may be interposed between the support plate PT and the second digitizer DGT2 to attach the support plate PT and the second digitizer DGT2 to each other.

FIG. 3 illustrates that the electronic device ED includes the first adhesive layer through the seventh adhesive layer AL1 through AL7, but the present disclosure is not limited thereto. In one or more embodiments of the present disclosure, another adhesive layer may be added or at least one of the first adhesive layer through the seventh adhesive layer AL1 through AL7 may not be provided.

Digitizers DGT1, DGT2 may be disposed below the support plate PT. The digitizers DGT1, DGT2 may include a first digitizer DGT1 and a second digitizer DGT2. The first digitizer DGT1 may be disposed on a position overlapping with the first non-foldable area NFA1. The second digitizer DGT2 may be disposed on a position overlapping with the second non-foldable area NFA2. At least a portion of the first digitizer DGT1 and the second digitizer DGT2, respectively, may be disposed on a lower side of the protection member PM. The first digitizer DGT1 and the second digitizer DGT2 may be disposed with a pre-determined gap therebetween. The pre-determined gap may be preferably about greater than or equal to 0.3 mm and smaller than or equal to 3 mm. However, the present disclosure is not limited thereto.

The digitizers DGT1, DGT2 may be configured to detect an input by an electromagnetic pen (not shown). The digitizers DGT1, DGT2 may be driven using a method based on electromagnetic resonance (EMR).

The digitizers DGT1, DGT2 may include a plurality of loop coils (not shown). The plurality of loop coils may be configured to generate a magnetic field at a pre-set resonant frequency with an electric pen. The magnetic field generated by the plurality of loop coils may be applied to an LC resonance circuit including an inductor and a capacitor of the electric pen. The coil may be configured to generate a current by the received magnetic field and transfer the generated current to the capacitor. Accordingly, the capacitor may be configured to charge the current received from the coil and discharge the charged current back to the coil. Eventually, a magnetic field of a resonant frequency may be emitted from the coil. The magnetic field emitted by the electric pen may be re-absorbed by the plurality of loop coils. Therefore, a position of the electric pen on the display panel DP may be determined.

Although it is not explicitly illustrated herein, an electromagnetic shielding layer (not shown) may be disposed below the digitizers DGT1, DGT2. The electromagnetic shielding layer (not shown) may have a function of electromagnetic shielding. For example, the electromagnetic shielding layer may be configured to block electromagnetic waves generated by an element disposed below the digitizers DGT1, DGT2. Accordingly, sensibility of the digitizers DGT1, DGT2 may be improved.

The electromagnetic shielding layer (not shown) may include magnetic metal powder (MMP), ferrite, or invar. In addition, the electromagnetic shielding layer (not shown) may include iron (Fe), silicon (Si), or aluminum (Al).

Metallic layers ML1, ML2 may be disposed below the digitizers DGT1, DGT2. The metallic layers ML1, ML2 may include a first metallic layer ML1 and a second metallic layer ML2. The first metallic layer ML1 may be disposed in an area corresponding to the first non-foldable area NFA1. The second metallic layer ML2 may be disposed in an area corresponding to the second non-foldable area NFA2.

The metallic layers ML1, ML2 may include stainless (SUS), copper (Cu), or aluminum (Al). However, the present disclosure is not limited thereto.

Although it is not explicitly illustrated, a heat dissipation layer (not shown) may be disposed below the metallic layers ML1, ML2. The heat dissipation layer may be configured to dissipate heat generated upon operation of the digitizers DGT1, DGT2.

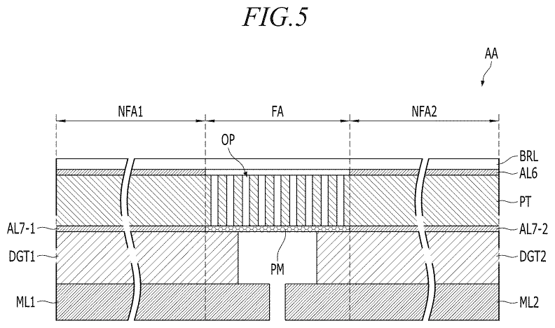

FIG. 4 is an illustration of a cross-section of the display panel DP according to one embodiment of the present disclosure.

Referring to FIG. 4, the display panel DP may include a substrate SB, a circuit layer CL, a light-emitting diode layer LD, and an encapsulation layer TFE.

The substrate SB may provide a basis for disposition of the circuit layer CL. The substrate SB may be a flexible substrate capable of, for example, bending, folding or rolling. The substrate SB may be, for example, a glass substrate, a metallic substrate, or a polymer substrate.

The substrate SB may be formed of polyethersulphone (PES), polyacrylate (PA), polyarylate (PAR), polyetherimide (PEI), polyethylene napthalate (PEN), polyethylene terephthalate (PET), polyphenylene sulfide (PPS), polyallylate, polycarbonate (PC), cellulosetriacetate (CAT), cellulose acetate propionate (CAP), or a combination thereof. However, the present disclosure is not limited thereto.

The circuit layer CL may be disposed on the substrate SB. The circuit layer CL may include, for example, a conductive pattern (not shown), a semiconductor pattern (not shown), a plurality of insulating layers (not shown), and a signal line (not shown).

The light-emitting diode layer LD may be disposed on the circuit layer CL. The light-emitting diode layer LD may include electrodes (not shown), functional layers (not shown), and a light-emitting diode (not shown). The light-emitting diode may include an organic light-emitting material, an inorganic light-emitting material, an organic-inorganic light-emitting material, a quantum dot, a quantum rod, a micro-LED, or a nano LED.

The encapsulation layer TFE may be disposed on the light-emitting diode layer LD. The encapsulation layer TFE may be configured to protect the light-emitting diode layer LD from an impurity such as moisture, oxygen, and a dust particle. The encapsulation layer TFE may include an inorganic layer and an organic layer. For example, the encapsulation layer TFE may have a structure of a first inorganic layer (not shown), an organic layer (shown), and a second inorganic layer (not shown) sequentially laminated.

Although it is not explicitly illustrated herein, an input detection sensor (not shown) and a reflection protection layer (not shown) may be disposed on the display panel DP.

The input detection sensor (not shown) may be disposed directly on the display panel DP. The input detection sensor (not shown) may be driven through a capacitive method. The input detection sensor (not shown) may be configured to detect a position or intensity of a user's touch. The input detection sensor (not shown) may include insulated detection electrodes, routing wires connected to the corresponding detection electrodes, and at least one detection insulating layer.

The reflection protection layer (not shown) may be directly disposed on the input detection sensor (not shown). The reflection protection layer (not shown) may be configured to reduce reflectivity of external light incident from outside. The reflection protection layer (not shown) may include color filters.

FIG. 5 is an magnified view of the AA area shown in FIG. 3.

Descriptions about components that are same as those in FIG. 3 will be omitted in the descriptions about FIG. 5. Referring to FIG. 5, because the support plate PT has a lattice shape, impact resistance and a capability for preventing penetration of an impurity in the foldable area FA may be weak. Thus, an element configured to increase the impact resistance and prevent penetration of an impurity into the lattice is necessary.

The protection member PM may overlap with the foldable area FA of the support plate PT. In addition, the protection member PM may overlap with at least any one of the plurality of opening parts OP. The protection member PM may improve impact resistance of the support plate PT and be configured to prevent penetration of an impurity into the lattice. Hereinafter, in the present disclosure, shear thickening fluid may be used to manufacture a protection member PM. Accordingly, descriptions about shear thickening liquid fluid will be followed.

FIG. 6A and FIG. 6B are graphs illustrating a physical feature of a protection member PM according to one embodiment of the present disclosure.

Generally, a liquid may include a Newtonian fluid and a non-Newtonian fluid. Here, a fluid refers to a suspension or a colloid in which fine particles are dispersed in a continuous solvent.

A Newtonian fluid has a constant viscosity regardless of a change in a shear strain rate. A non-Newtonian fluid has a changing viscosity when a shear strain rate changes. Here, a shear strain rate refers to a speed of a liquid when shear stress is applied. In addition, a viscosity is a quantitative measure of a fluid's resistance to flow, and the higher the viscosity, the worse the flow.

Referring to FIG. 6A, zone I demonstrates a particle arrangement of a Newtonian fluid. The Newtonian fluid shows a constant viscosity regardless of a shear strain rate. This may be in an equilibrium state. [1] in FIG. 6B illustrates an instantaneous rate of change in shear stress versus shear strain rate of a Newtonian fluid.

Referring to FIG. 6A, zone II demonstrates a particle arrangement of a non-Newtonian fluid in a shear thinning state. In a shear thinning state, an arrangement of particles changes regularly as the shear strain rate changes. In addition, resistance against flow of a fluid decreases, thus, viscosity decreases. Accordingly, a shear thinning fluid is in a liquid state. [2] in FIG. 6B illustrates an instantaneous rate of change in shear stress versus shear strain rate in a shear thinning state.

Referring to FIG. 6A, zone III demonstrates a particle arrangement of a non-Newtonian fluid in a shear thickening state. When an external force is applied to a non-Newtonian fluid and a certain critical shear strain rate is reached, the particles aggregate and the viscosity rapidly increases. The aggregated particles are referred as a hydrocluster. Due to the hydrocluster, resistance against flow of a liquid increases, thus, viscosity increases. Accordingly, shear thickening liquid has a same property as a solid. However, if an external on the shear thickening fluid is removed, the shear thickening fluid may exhibit a reversible response, covering its original fluidity. [3] in FIG. 6B illustrates an instantaneous rate of change, which is a rate of change of a quantity at a specific point in time, in shear stress according to shear strain rate in a shear thickening state.

In one embodiment of the present disclosure, in the protection member PM, an instantaneous rate of change of the second shear stress ST2 corresponding to the second shear strain rate SRT2 which is greater than the first shear strain rate SRT1 may be greater than an instantaneous rate of change of the first shear stress ST1 corresponding to the first shear strain rate SRT1. The instantaneous rate of change may refer to a slope in graph [3].

Impact resistance of a display panel DP may be improved by using such shear thickening fluid to protect the display panel DP. Hereinafter, experimental results thereof will be described.

An external impact experiment was performed to measure impact resistance of a display panel DP. The external impact experiment will be described based on a ball drop test. The ball drop test is a method of fixing a display panel DP at a drop location to receive an impact and free dropping a ball in a vertical direction to the drop location. Here, a weight of the ball is not specifically limited. However, a weight of the ball may be about greater than or equal to 100 g and smaller than or equal to 1000 g as an example.

Experimental conditions of Example 1, Example 2, Example 3, and Example 4 were as shown in Table 1 below. Here, Example 4 shows experimental results of application of a structure of the present disclosure.

TABLE 1

| | | Exam- | Exam- | Exam- | Exam- |
|---|---|---|---|---|---|
| | | ple 1 | ple 2 | ple 3 | ple 4 |
| Struc- | Window | Hard | Hard | Hard | Hard |
| ture | Protection | film | film | film | film |
| | Layer (WP) | | | | |
| | Window | Glass | Polyethylene | Elastomer | Elastomer |
| | (WN) | | terephthalate | | |
| | | | (PET) | | |
| | Lower | Thermo- | Thermo- | Thermo- | Protection |
| | Member | plastic | plastic | plastic | Member |
| | | polyure- | polyure- | polyure- | PM |
| | | thane | thane | thane | |
| | | (TPU) | (TPU) | (TPU) | |
| Hight of | Non-foldable | 23 | 25 | 38 | 38 |
| ball | areas | | | | |
| drop | (NFA1, | | | | |
| (cm) | NFA2) | | | | |
| | Foldable | 0 | 0 | 0 | 4 |
| | area (FA) | | | | |

In Table 1, the higher the height of the ball drop, the more improved impact resistance of the display panel DP against an external impact.

In each of the Example 1 through Example 4, an electronic device ED comprised a window protection layer WP, a window WN, a display panel DP, a panel protection layer PPL, a support plate PT, and a lower member. A varying structure in the experiment was the window WN and the lower member. In the present disclosure, the lower member refers to an element disposed at a position of a protection member PM (see FIG. 3).

In Example 1, ultra-thin glass (UTG) was applied to a window WN and thermoplastic polyurethane (TPU) was used as a lower member. A modulus of the ultra-thin glass may be greater than or equal to about 50 GPa. In Example 1, the non-foldable areas NFA1, NFA2 were able to withstand the impact without being damaged when a ball was dropped from a height of 23 cm.

In Example 2, polyethylene terephthalate (PET) was applied to a window WN and thermoplastic polyurethane (TPU) was used as a lower member. Unlike Example 1, a different material was used for the window WN in Example 2. A modulus of the window WN in Example 2 may be about greater than or equal to 3.5 GPa. In Example 2, the non-foldable areas NFA1, NFA2 were able to withstand the impact without being damaged when a ball was dropped from a height of 25 cm. In comparison to Example 1, the impact resistance was improved by about 8%.

In Example 3, an elastomer was applied to the window WN, and thermoplastic polyurethane (TPU) was used as a lower member. Unlike Example 2, a different material was used for the window WN in Example 3. A modulus of the window WN in Example 3 may be about less than or equal to 0.9 GPa. In Example 3, the non-foldable areas NFA1, NFA2 were able to withstand an impact without being damaged when a ball was dropped from a height of 38 cm. In comparison to Example 2, the impact resistance was improved by about 52%.

However, a height of the ball drop was 0 cm in a foldable area FA in all of Examples 1 to 3. This shows that the configurations of Examples 1 to 3 do not provide a cushioning effect to protect the foldable area FA.

In Example 4, an elastomer was applied to the window WN, and a protection member PM was used for the lower member. The protection member PM of the present disclosure may include a foam type material including shear-thickening material. Similar to Example 3, the non-foldable areas NFA1, NFA2 were able to withstand an impact without being damaged when a ball was dropped from a height of 38 cm in Example 4. In addition, in Example 4, the foldable area FA was able to withstand an impact without being damaged when a ball was dropped from a height of 4 cm. Unlike Examples 1 to 3, impact resistance of the foldable area FA was improved in Example 4.

Therefore, the configuration of the present disclosure may improve impact resistance. Particularly, it was possible to improve weak durability of the foldable area FA of the display panel DP. In addition, the protection member PM may be configured to prevent penetration of an impurity into a lattice.

In one embodiment of the present disclosure, the protection member PM could have a modulus of greater than or equal to about 50 MPa and smaller than or equal to about 150 MPa at a room temperature (greater than or equal to about 19° C. and smaller than or equal to about 21° C.). The protection member PM may have a modulus of about greater than or equal to 400 MPa and smaller than or equal to 1 GPa at a lower temperature (greater than or equal to about-19° C. and smaller than or equal to about −21° C.).

In one embodiment of the present disclosure, a thickness of the protection member PM may be greater than or equal to 8 μm and smaller than or equal to 4 mm. If the thickness of the protection member PM is less than 8 μm, the protection member PM may not be configured to effectively absorb an impact applied to the lattice and prevent sagging of the lattice. If a thickness of the protection member PM exceeds 4 mm, flexibility of the lattice may be reduced, thereby degrading foldability or bendability feature of the electronic device ED.

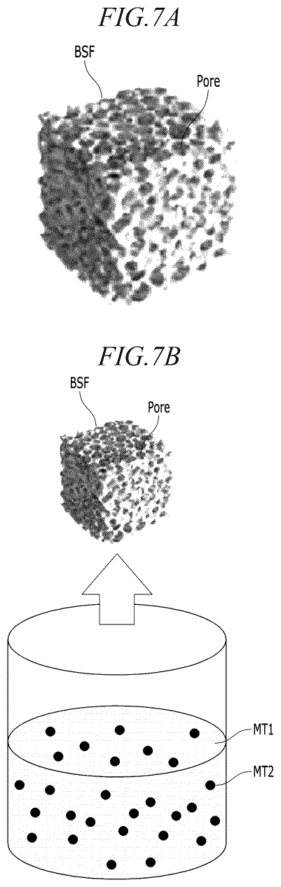

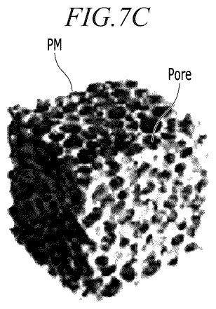

FIG. 7A through FIG. 7C are illustrations of a manufacturing process of a protection member PM according to one embodiment of the present disclosure. As described in FIG. 6A and FIG. 6B, because the shear-thickening fluid exhibits a rapid increase in viscosity when an external force is applied, it behaves like a solid when an external force is applied to the shear-thickening fluid. A protection member PM using such shear-thickening fluid may be configured to protect the display panel DP and improve impact resistance feature of the electronic device ED. However, because the shear-thickening fluid is a fluid, there is a difficulty in manufacturing in a film type. Therefore, the present disclosure relates to manufacture of the protection member PM including a shear-thickening material in a foam type.

Referring to FIG. 7A, a base member BSF may be provided.

The base member BSF may have a porous structure in which pores are disposed in the base member. The base member BSF may be a fabric having a woven or non-woven structure. A plurality of pores may be defined in the base member BSF. For example, the base member BSF may include acryl, urethane, or polyurethane having a plurality of pores.

Referring to FIG. 7B, a shear-thickening fluid may be provided and impregnated into the base member BSF.

In one embodiment of the present disclosure, the shear-thickening fluid may include a mixture of an organic dispersing fluid and inorganic nanoparticles dispersed in the organic dispersing liquid. The organic dispersing fluid in the present disclosure may be referred as a first material MT1. The inorganic nanoparticle may be referred as a second material MT2.

In the present disclosure, the organic dispersing liquid may include, for example, polyethylene glycol (PEG), ethylene glycol (EG), and polypropylene glycol (PPG). Particularly, the organic dispersing liquid may be polyethylene glycol (PEG). The polyethylene glycol (PEG) has a feature of low volatility and a boiling point higher than or equal to 200° C., making it thermally stable and suitable for use as a dispersing solvent. However, the present disclosure is not limited thereto. As other examples, the organic dispersing liquid may include, for example, methanol, ethanol, isopropanol, or diethylene glycol.

In the present disclosure, the inorganic nanoparticles may include silica (SiO₂), calcium carbonate (CaCO₃), polystyrene (PS), and polymethyl methacrylate (PMMA). However, the present disclosure is not limited thereto, and in other examples, the inorganic nanoparticles may include aluminum oxide, zirconia, titanium oxide, calcium carbonate, and/or hydrotalcite. Various materials may be used for the inorganic nanoparticles taking into account of factors such as particle size, shape, structure, and interaction with the organic dispersing liquid.

In case that the inorganic nanoparticles are silica (SiO2), the silica may be in a fumed type or a spherical silica type. A size of the silica particles may be about 20 to about 600 nm. When the size of the silica particles is less than 20 nm, the critical shear rate may increase excessively and, when the size exceeds 600 nm, the onset of shear thickening may be delayed. However, the present disclosure is not limited thereto.

In addition, in the present disclosure, the inorganic nanoparticles may further include carbon nanotube and nanofiber. The carbon nanotube is a material having carbon atoms combined in hexagonal honeycomb structure to form a tubular shape. The carbon nanotube has excellent electrical conductivity, high thermal conductivity, and mechanical properties of high strength and high elasticity. Using the carbon nanotube may lead to achievement of higher viscosity and manufacture of a shear-thickening fluid with much lighter weight. However, the carbon nanotube is difficult to disperse in a fluid. Accordingly, a surfactant may be added to improve dispersibility of the carbon nanotube.

In FIG. 7B, preparing a shear-thickening fluid, and impregnating the shear-thickening fluid in the base member BSF may be performed. As described above, the preparing a shear-thickening fluid may include dissolving an inorganic nanoparticle MT2 in an organic dispersing liquid MT1. Subsequently, impregnating the shear-thickening fluid in a base member BSF may be performed.

Referring to FIG. 7C, drying the impregnated base member BSF by the shear-thickening fluid (not shown) may be performed. In the drying, solvent remaining on the base member BSF may be evaporated. Eventually after the drying, a protection member PM in a foam type including a shear-thickening material may be completed.

As the protection member PM has gone through impregnation of the shear-thickening fluid, in one embodiment of the present disclosure, the protection member PM may include a first material MT1 and a second material MT2. The first material MT1 and the second material MT2 are as described above.

In addition, because the protection member PM is manufactured based on the base member BSF, the protection member PM may include a same material as the base member BSF. In one embodiment of the present disclosure, the protection member PM may include at least any one of urethane, acryl, and thermoplastic polyurethane (TPU).

In summary from FIG. 6A through FIG. 7C, the shear-thickening fluid exhibits properties of a liquid under normal conditions, however, when subjected to shear force due to external impact, its viscosity increases rapidly, causing it to behave like a solid. Because the protection member PM manufactured using a shear-thickening fluid has similar properties with the shear-thickening fluid, it may provide a cushioning effect against an external impact. Therefore, the protection member PM of the present disclosure may be configured to protect the electronic device ED from an impact when the electronic device ED is repeatedly bent, folded or rolled.

FIG. 8A through FIG. 8E each is a magnified view of a portion of a cross-section of an electronic device ED according to another embodiment of the present disclosure.

In descriptions about FIG. 8A through FIG. 8E, descriptions about same elements as in FIG. 3 and FIG. 5 are omitted. Descriptions about FIG. 8A through FIG. 8E are focused on disposition of the protection member PM-1, PM-2, PM-3, PM-4, PM-5.

FIG. 8A is a magnified view of a portion AA-1 of a cross-section of an electronic device ED according to another embodiment of the present disclosure. The electronic device ED may include a barrier layer BRL, a sixth adhesive layer AL6, a support plate PT, a seventh adhesive layer AL7-1, AL7-2, a protection member PM-1, digitizers DGT1, DGT2 and metallic layers ML1, ML2.

In another embodiment of the present disclosure, at least some portion of the protection member PM-1 may be disposed in the plurality of opening parts OP. FIG. 8A illustrates that the protection member PM-1 is disposed in the plurality of opening parts OP.

In comparison to FIG. 5, the protection member PM-1 may be disposed in the plurality of opening parts OP of the support plate PT and configured to effectively prevent sagging of the support plate PT towards below.

FIG. 8B is a magnified view of a portion AA-2 of a cross-section of an electronic device ED according to yet another embodiment of the present disclosure. FIG. 8B differs from FIG. 8A merely in a portion of disposition of the protection member PM-2.

In another embodiment of the present disclosure, at least any portion of the protection member PM-2 may be disposed below the support plate PT and disposed to overlap with at least any one of the first non-foldable area NFA1 and the second non-foldable area NFA2.

FIG. 8B illustrates that the protection member PM-2 completely overlaps with the first non-foldable area NFA1, the foldable area FA, and the second non-foldable area NFA2. Accordingly, the seventh adhesive layer AL7-1, AL7-2 (see FIG. 8A) configured to attach the support plate PT and the digitizers DGT1, DGT2 is omitted. However, the present disclosure is not limited thereto. For example, the protection member PM-2 may overlap with the first non-foldable area NFA1 and the foldable area FA, and not overlap with the second non-foldable area NFA2. In another embodiment, the protection member PM-2 may overlap with the second non-foldable area NFA2 and the foldable area FA, and not overlap with the first non-foldable area NFA1. In comparison to FIG. 8A, the protection member PM-2 shown in FIG. 8B may be disposed entirely on a lower surface of the support plate PT to more effectively prevent sagging of the support plate PT.

FIG. 8C is a magnified view of a portion AA-3 of a cross-section of an electronic device ED according to another embodiment of the present disclosure. In FIG. 8C, only a position of a disposition of the protection member PM-3 among configuration of FIG. 8A is changed.

In another embodiment of the present disclosure, at least some of the protection member PM-3 may be disposed in the plurality of opening parts OP. FIG. 8C illustrates that the protection member PM-3 is disposed in the plurality of opening parts OP.

In another embodiment of the present disclosure, at least some of the protection member PM-3 may overlap with at least any one of the plurality of opening parts OP in a plan view. FIG. 8C illustrates that the protection member PM-3 is disposed below the support plate PT to overlap with the plurality of opening parts OP.

In comparison to FIG. 8B, the protection member PM-3 may be disposed below the support plate PT and in the plurality of opening parts OP to more effectively absorb impacts applied to the support plate PT. In addition, the protection member PM-3 shown in FIG. 8C may be configured to more effectively prevent sagging of the support plate PT towards below.

FIG. 8D is a magnified view of a portion AA-4 of a cross-section of an electronic device ED according to another embodiment of the present disclosure. In FIG. 8D, only a position of a disposition of the protection member PM-4 among the configuration of FIG. 8C is changed.

Referring to FIG. 8D, the protection member PM-4 may be further disposed between the digitizers DGT1, DGT2 as compared to the protection member disclosed in FIG. 8C.

In another embodiment of the present disclosure, at least any some of the protection member PM-4 may be disposed between the first digitizer DGT1 and the second digitizer DGT2. As described in FIG. 3, the first digitizer DGT1 and the second digitizer DGT2 may be spaced apart with the pre-determined gap therebetween. FIG. 8D illustrates a structure where the protection member PM-4 is disposed in the pre-determined gap to fill empty space. In a flexible display device, empty space between each configuration may be a factor to degrade impact resistance of the flexible display device. Particularly, if there is an empty space above or below the support plate PT, impact resistance of the flexible display device may be degraded. Therefore, as shown in FIG. 8D, the protection member PM-4 may be configured to further effectively protect a display device by filling a gap between the first digitizer DGT1 and the second digitizer DGT2 with the protection member PM-4.

FIG. 8E is a magnified view of a portion AA-5 of a cross-section of an electronic device ED according to another embodiment of the present disclosure. In FIG. 8E, only a position of disposition of the protection member PM-5 among the configuration of FIG. 8D is changed.

Referring to FIG. 8E, the protection member PM-5 may further be disposed above the support plate PT as compared to the protection member disclosed in FIG. 8D.

In another embodiment of the present disclosure, at least some of the protection member PM-5 may be disposed between the display panel DP (see FIG. 3) and the support plate PT. Particularly, at least some of the protection member PM-5 may be disposed between the barrier layer BRL and the support plate PT. The structure as shown in FIG. 8E may have a protection member PM-5 disposed above and below the support plate PT to effectively prevent sagging of the support plate PT. In addition, when the foldable area FA of the support plate PT is repeatedly folded or bent, the protection member PM-5 may be configured to absorb impact better.

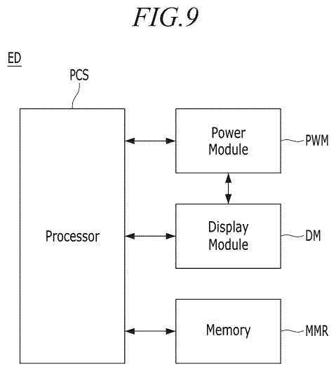

FIG. 9 is an illustration of a block diagram of an electronic device ED according to one embodiment of the present disclosure. As described herein, the electronic device ED according to one embodiment of the present disclosure may include a display device, and further include a module or a device having additional functions further to the display device.

Referring to FIG. 9, the electronic device ED according to one embodiment of the present disclosure may include a display module DM, a processor PCS, a memory MMR, and a power module PWM.

The processor PCS may include at least one of a central processing unit (CPU), an application processor (AP), a graphic processing unit (GPU), a communication processor (CP), an image signal processor (ISP), and a controller.

The memory MMR may be configured to store data information necessary for operation of the processor PCS or the display module DM. When the processor PCS executes an application stored in the memory MMR, an image data signal and/or an input control signal may be transferred to the display module DM, which may then process the received signals and output image information through a display screen.

The power module PWM may include a power supply module such as a power adapter or a battery device, and a power conversion module configured to convert the power supplied by the power supply module into power required for the operation of the electronic device ED.

At least one of the above-described components of the electronic device ED may be included within the display device DD according to the above-described embodiments. Additionally, certain individual modules included functionally within a single module may be provided within the display device while other individual modules may be provided outside the display device. For instance, the display device may include the display module DM, and the processor PCS, memory MMR, and power module PWM may be provided as other devices within the electronic device ED but not within the display device.

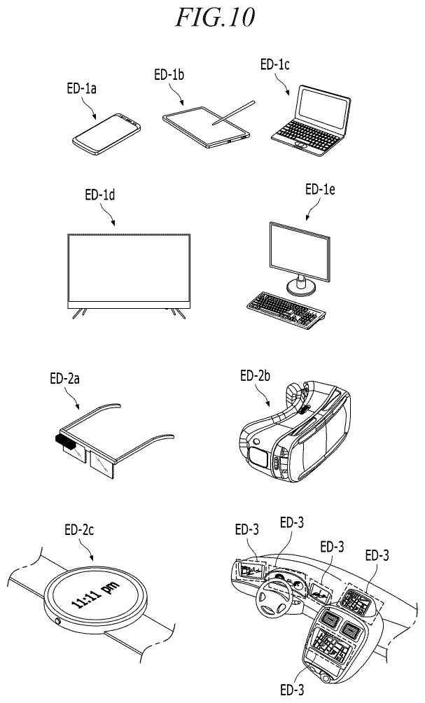

FIG. 10 are exemplary schematic diagrams of electronic devices ED according to various embodiments of the present disclosure.

Referring to FIG. 10, various electronic devices ED applied with a display device according to the embodiments may include not only an electronic device for displaying an image, such as a smartphone (ED-1a), a tablet PC (ED-1b), a laptop (ED-1c), a TV (ED-1d), and a desk monitor (ED-1e), but also a wearable electronic device including a display module, such as a smart glasses (ED-2a), a head-mounted display (ED-2b), and a smartwatch (ED-2c), and an electronic device for a vehicle including a display module ED-3, such as a dashboard of an automobile, a center fascia, CID (Center Information Display) disposed on a dashboard, and a room mirror display.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display device comprising:
a display module comprising a display panel including a first non-foldable area, a foldable area, and a second non-foldable area, the foldable area being disposed between the first non-foldable area and the second non-foldable area;
a support plate disposed below the display panel and having a plurality of opening parts overlapping with the foldable area in a planar view defined therein; and
a protection member overlapping with at least one of the plurality of opening parts in a planar view and including shear-thickening material.

2. The display device of claim 1,
wherein the protection member comprises a first material and a second material,
wherein the first material comprises at least one of polyethylene glycol (PEG) and polypropylene glycol (PPG), and
wherein the second material comprises at least one of silicon dioxide (SiO2), calcium carbonate (CaCO3), polystyrene (PS), and polymethyl methacrylate (PMMA).

3. The display device of claim 2,
wherein at least a portion of the protection member is disposed below the support plate to overlap with at least one of the first non-foldable area and the second non-foldable area.

4. The display device of claim 2,
wherein at least a portion of the protection member is disposed in the plurality of opening parts.

5. The display device of claim 2,
wherein at least a portion of the protection member is disposed between the display panel and the support plate.

6. The display device of claim 2, further comprising:
a first digitizer disposed below the support plate and overlapping with the first non-foldable area; and
a second digitizer disposed below the support plate, overlapping with the second non-foldable area and spaced apart from the first digitizer,
wherein at least a portion of the protection member is disposed between the first digitizer and the second digitizer.

7. The display device of claim 2,
wherein in the protection member, an instantaneous rate of change of a second shear thickening corresponding to a second shear thickening rate greater than the first shear thickening rate is greater than an instantaneous rate of change of a first shear thickening corresponding to a first shear rate.

8. The display device of claim 7,
wherein the protection member has a modulus greater than or equal to 50 MPa and smaller than or equal to 150 MPa at a temperature greater than or equal to 19° C. and smaller than or equal to 21° C., and
wherein the protection member has a modulus greater than or equal to 400 MPa and smaller than or equal to 1 GPa at a temperature greater than or equal to −19° C. and smaller than or equal to −21° C.

9. The display device of claim 8,
wherein the protection member has a thickness greater than or equal to 8 μm and smaller than or equal to 4 mm.

10. The display device of claim 2,
wherein the protection member further comprises at least one of carbon nanotube (CNT) and nano-fiber.

11. The display device of claim 2,
wherein the protection member further comprises at least one of urethane, acryl, and thermoplastic polyurethane (TPU).

12. The display device of claim 2, further comprising a window disposed on the display module,
wherein the window comprises elastomer.

13. The display device of claim 12,
wherein the window has a modulus greater than or equal to 0.1 MPa and smaller than or equal to 0.9 GPa at a temperature greater than or equal to 19° C. and smaller than or equal to 21° C., and
wherein the window has a modulus greater than or equal to 0.1 MPa and smaller than or equal to 2 GPa at a temperature greater than or equal to −19° C. and smaller than or equal to −21° C.

14. The display device of claim 13,
wherein the window has a thickness greater than or equal to 16 μm and smaller than or equal to 85 μm.

15. An electronic device comprising:
a display module comprising a display panel having a first non-foldable area, a foldable area, and a second non-foldable area defined therein, the foldable area being disposed between the first non-foldable area and the second non-foldable area;
a support plate disposed below the display panel and having a plurality of opening parts overlapping with the foldable area in a planar view defined therein; and
a protection member overlapping with at least one of the plurality of opening parts in a planar view,
wherein in the protection member, an instantaneous rate of change of a second shear thickening corresponding to a second shear thickening rate greater than the first shear thickening rate is greater than an instantaneous rate of change of a first shear thickenings corresponding to a first shear rate.

16. The electronic device of claim 15,
wherein the protection member comprises a first material and a second material,
wherein the first material comprises at least one of polyethylene glycol (PEG) and polypropylene glycol (PPG), and
wherein the second material comprises at least one of silicon dioxide (SiO2), calcium carbonate (CaCO3), polystyrene (PS), and polymethyl methacrylate (PMMA).

17. The electronic device of claim 16,
wherein at least a portion of the protection member is disposed below the support plate to overlap with at least any one of the first non-foldable area and the second non-foldable area.

18. The electronic device of claim 16,
wherein at least a portion of the protection member is disposed in the plurality of opening parts.

19. The electronic device of claim 16,
wherein at least a portion of the protection member is disposed between the display panel and the support plate.

20. The electronic device of claim 16,
wherein the protection member has a modulus greater than or equal to 50 MPa and smaller than or equal to 150 MPa at a temperature greater than or equal to 19° C. and smaller than or equal to 21° C., and
wherein the protection member has a modulus greater than or equal to 400 MPa and smaller than or equal to 1 GPa at a temperature greater than or equal to −19° C. and smaller than or equal to −21° C.
